(19) United States
(12) Patent Application Publication
(10) Pub. No.: US 2026/0271375 A1
(43) Pub. Date: Sep. 10, 2026

(54) SEMICONDUCTOR DEVICE AND PHOTORELAY CIRCUIT

(71) Applicant: KABUSHIKI KAISHA TOSHIBA, Kawasaki-shi (JP)

(72) Inventors: Tomoaki INOKUCHI, Yokohama Kanagawa (JP); Yusuke KOBAYASHI, Yokohama Kanagawa (JP); Shotaro BABA, Kawasaki Kanagawa (JP); Hiroki NEMOTO, Meguro Tokyo (JP)

(73) Assignee: KABUSHIKI KAISHA TOSHIBA, Kawasaki-shi (JP)

(21) Appl. No.: 19/453,008

(22) Filed: Jan. 20, 2026

(30) Foreign Application Priority Data
Mar. 4, 2025 (JP) 2025-033769

(51) Int. Cl. H10D 84/00; H03K 17/78; H10D 64/00

(52) U.S. Cl. CPC H10D 84/146; H03K 17/78; H10D 64/117

(57) ABSTRACT

According to one embodiment, a semiconductor device includes an element portion. The element portion includes first to third electrodes, a semiconductor member, and a first insulating member. The semiconductor member includes a first semiconductor region of a first conductivity type, and a second semiconductor region of the first conductivity type. A second impurity concentration of the first conductivity type in the second semiconductor region is higher than a first impurity concentration of the first conductivity type in the first semiconductor region. The first semiconductor region includes a first partial region, a second partial region, and a third partial region. The first partial region is between the first electrode and the third electrode in the first direction. The first electrode portion is in Schottky contact with the semiconductor member. The element portion is a transistor configured to operate normally-ON.

### CROSS-REFERENCE TO RELATED APPLICATIONS

This application is based upon and claims the benefit of priority from Japanese Patent Application No. 2025-033769, filed on Mar. 4, 2025; the entire contents of which are incorporated herein by reference.

### FIELD

Embodiments described herein relate generally to a semiconductor device and a photorelay circuit.

### BACKGROUND

For example, in semiconductor devices, improvements in characteristics are desired.

### BRIEF DESCRIPTION OF THE DRAWINGS

FIG. 1 is a schematic cross-sectional view illustrating a semiconductor device according to a first embodiment;

FIG. 2 is a graph illustrating the characteristics of the semiconductor device;

FIG. 3 is a schematic cross-sectional view illustrating a semiconductor device according to the first embodiment;

FIG. 4 is a schematic cross-sectional view illustrating a semiconductor device according to the first embodiment; and

FIG. 5 is a schematic diagram illustrating a semiconductor device according to a second embodiment.

### DETAILED DESCRIPTION

According to one embodiment, a semiconductor device includes an element portion. The element portion includes a first electrode, a second electrode including a first electrode portion, a direction from the first electrode to the second electrode being along a first direction, a third electrode, a semiconductor member, and a first insulating member. A second direction from the third electrode to the first electrode portion crosses the first direction. At least a part of the first insulating member is between the third electrode and the semiconductor member. The semiconductor member includes a first semiconductor region of a first conductivity type, and a second semiconductor region of the first conductivity type. A second impurity concentration of the first conductivity type in the second semiconductor region is higher than a first impurity concentration of the first conductivity type in the first semiconductor region. The first semiconductor region includes a first partial region, a second partial region, and a third partial region. The first partial region is between the first electrode and the third electrode in the first direction. A direction from the first partial region to the second partial region is along the second direction. The second partial region is between the first electrode and the second electrode in the first direction. The third partial region is between the second partial region and the second electrode in the first direction. A direction from a part of the third electrode to the third partial region is along the second direction. At least a part of the second semiconductor region is between the third partial region and the second electrode in the first direction. At least a part of the second semiconductor region is between the third electrode and the first electrode portion in the second direction. The first electrode portion is in Schottky contact with the semiconductor member. The element portion is a transistor configured to operate normally-ON.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

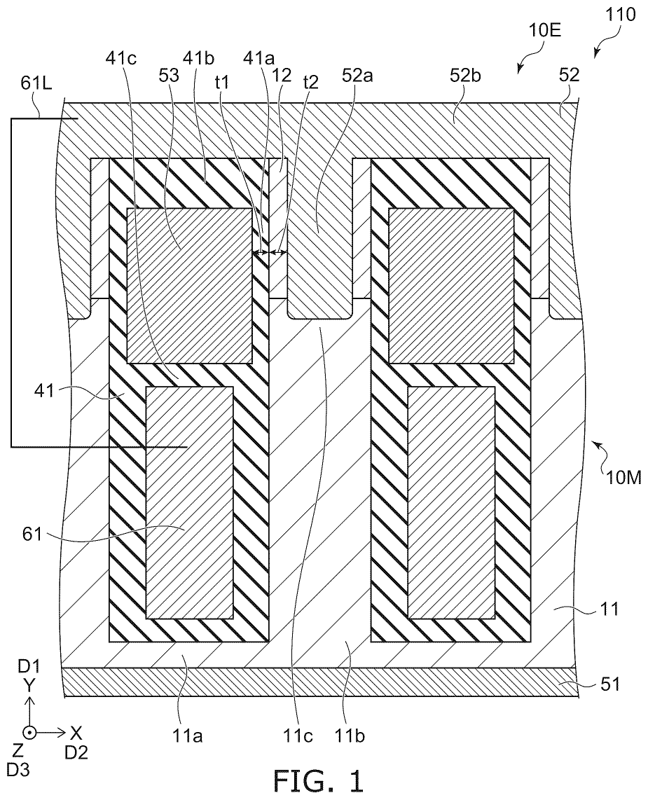

FIG. 1 is a schematic cross-sectional view illustrating a semiconductor device according to a first embodiment.

As shown in FIG. 1, a semiconductor device 110 according to the embodiment includes an element portion 10E. The element portion 10E includes a first electrode 51, a second electrode 52, a third electrode 53, a semiconductor member 10M, and a first insulating member 41.

The second electrode 52 includes a first electrode portion 52a. A direction from the first electrode 51 to the second electrode 52 is along a first direction D1. The first direction D1 is defined as a Y-axis direction. One direction perpendicular to the Y-axis direction is defined as an X-axis direction. A direction perpendicular to the Y-axis direction and the X-axis direction is defined as a Z-axis direction.

A second direction D2 from the third electrode 53 to the first electrode portion 52a crosses the first direction D1. The second direction D2 may be, for example, the X-axis direction.

At least a part of the first insulating member 41 is between the third electrode 53 and the semiconductor member 10M. The first insulating member 41 insulates the third electrode 53 from the semiconductor member 10M.

The semiconductor member 10M includes a first semiconductor region 11 of a first conductivity type and a second semiconductor region 12 of the first conductivity type.

The first conductivity type may be n-type. In the embodiment, the first conductivity type may be p-type. In the following example, the first conductivity type is n-type.

A second impurity concentration of the first conductivity type in the second semiconductor region 12 is higher than a first impurity concentration of the first conductivity type in the first semiconductor region 11.

The first semiconductor region 11 includes a first partial region 11a, a second partial region 11b, and a third partial region 11c. The first partial region 11a is between the first electrode 51 and the third electrode 53 in the first direction D1. A direction from the first partial region 11a to the second partial region 11b is along the second direction D2. The second partial region 11b is between the first electrode 51 and the second electrode 52 in the first direction D1. The third partial region 11c is located between the second partial region 11b and the second electrode 52 in the first direction D1.

A direction from a part of the third electrode 53 to the third partial region 11c is along the second direction D2. At least a part of the second semiconductor region 12 is between the third partial region 11c and the second electrode 52 in the first direction D1. At least a part of the second semiconductor region 12 is between the third electrode 53 and the first electrode portion 52a in the second direction D2.

The first electrode portion 52a is in Schottky contact with the semiconductor member 10M. The element portion 10E is a transistor that operates normally-ON.

Current flowing between the first electrode 51 and the second electrode 52 can be controlled by a potential of the third electrode 53. The potential of the third electrode 53 may be, for example, a potential based on a potential of the second electrode 52. The first electrode 51 functions, for example, as a drain electrode. The second electrode 52 functions, for example, as a source electrode. The third electrode 53 functions as, for example, a gate electrode.

In the embodiment, the element portion 10E operates in a normally-ON mode. Stable depletion mode operation is obtained.

As shown in FIG. 1, a thickness of the second semiconductor region 12 along the second direction D2 is defined as a second semiconductor region thickness t2. In one example, the threshold voltage of the element portion 10E can be controlled by the second semiconductor region thickness t2, etc.

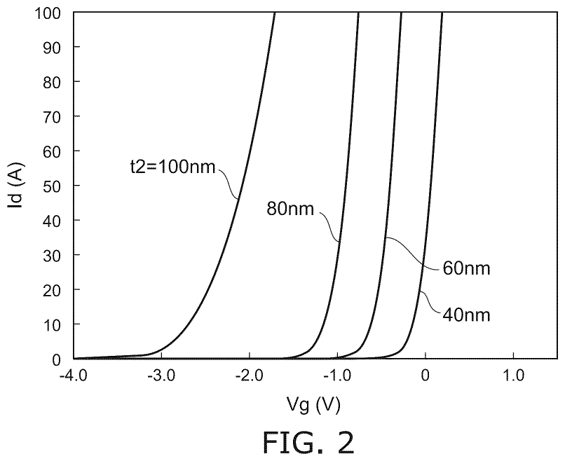

FIG. 2 is a graph illustrating the characteristics of a semiconductor device.

The horizontal axis of FIG. 2 is the gate voltage. The vertical axis is the drain current. FIG. 2 illustrates the characteristics when the second semiconductor region thickness t2 is changed.

As shown in FIG. 2, as the second semiconductor region thickness t2 increases, the threshold voltage decreases. By appropriately setting the second semiconductor region thickness t2, normally-ON operation can be obtained. For example, the second semiconductor region thickness t2 may be 80 nm or more. Normally-ON operation can be obtained. The second semiconductor region thickness t2 may be 100 nm or more. Normally-ON operation can be stably obtained. The second semiconductor region thickness t2 may be 500 nm or less. Practical characteristics can be obtained.

In the embodiment, the channel length can be shortened. As a result, the total gate charge (Qg) is small. The gate capacitance is small. As a result, high-speed switching can be obtained. Losses are small. For example, the gate capacitance (Cg) and the gate-drain capacitance (Cgd) are reduced. As a result, the total gate charge (Qg) and the gate-drain charge (Qgd) are reduced. As a result, losses can be reduced. For example, switching can be made faster. For example, the turn-on loss and the turn-off loss can be suppressed. In the embodiment, a MOSFET with high transconductance can be configured.

Transistors can be provided at a high density. The channel area per unit area can be increased. This allows, for example, a reduction in on-resistance. A large current can be switched.

In the embodiment, no hole injection occurs in the diode operation. This allows a small reverse recovery charge (Qrr). Losses can be reduced. Diode conduction losses can be reduced. For example, a low forward voltage VF can be obtained in the Schottky diode.

In the embodiment, the semiconductor member 10M includes silicon.

As shown in FIG. 1, in this example, the first electrode portion 52a contacts the first semiconductor region 11. The first electrode portion 52a is in Schottky contact with the first semiconductor region 11.

The first electrode portion 52a includes at least one element selected from the group consisting of Co, Ni, Pt, Ir, Se, Pd, Rh, Re, Mo, V, Ti, W, Ta, Zr, Al, Sn, Os, Nb, Ru, Sr, and Hf, an oxide including the above element, a nitride including the above element, or a silicide including the above element. A Schottky junction is obtained stably.

In this example, a part of the third partial region 11c is between the third electrode 53 and the first electrode portion 52a in the second direction D2.

In the embodiment, the third electrode 53 may include polysilicon. For example, the third electrode 53 may include a first element and silicon. The first element includes at least one selected from the group consisting of P, As, and Sb. The third electrode 53 may include, for example, n-type polysilicon. The third electrode 53 being stable is stably obtained.

As shown in FIG. 1, for example, the first insulating member 41 includes a first insulating region 41a. The first insulating region 41a is between the third electrode 53 and the second semiconductor region 12 in the second direction D2. A thickness of the first insulating region 41a along the second direction D2 is defined as a first insulating region thickness t1. The first insulating region thickness t1 may be, for example, not less than 20 nm and not more than 100 nm. Stable characteristics are obtained.

The second electrode 52 may further include a second electrode portion 52b. The third electrode 53 is between the first partial region 11a and the second electrode portion 52b in the first direction D1. In one example, the second electrode portion 52b may be in ohmic contact with the second semiconductor region 12. For example, the material of the second electrode portion 52b may be different from the material of the first electrode portion 52a.

The first insulating member 41 may include a second insulating region 41b. The second insulating region 41b is between the third electrode 53 and the second electrode portion 52b in the first direction D1.

The element portion 10E may further include a first conductive member 61. A position of the first conductive member 61 in the first direction D1 (first conductive member position) is between a position of the first partial region 11a in the first direction D1 (first partial region position) and a position of the third electrode 53 in the first direction D1 (third electrode position).

The first conductive member 61 is configured to be electrically connected to the second electrode 52. In this example, the first conductive member 61 is electrically connected to the second electrode 52 by a wiring 61L.

The first insulating member 41 may include a third insulating region 41c. The third insulating region 41c is between the first conductive member 61 and the third electrode 53. A part of the first insulating member 41 is between the first conductive member 61 and the third electrode 53, and between the first conductive member 61 and the semiconductor member 10M.

A plurality of third electrodes 53 may be provided. The plurality of third electrodes 53 are arranged along the second direction D2. The third electrodes 53 and the first conductive member 61 may extend along a third direction D3. The third direction D3 crosses a plane including the first direction D1 and the second direction D2. The third direction D3 may be, for example, the Y-axis direction.

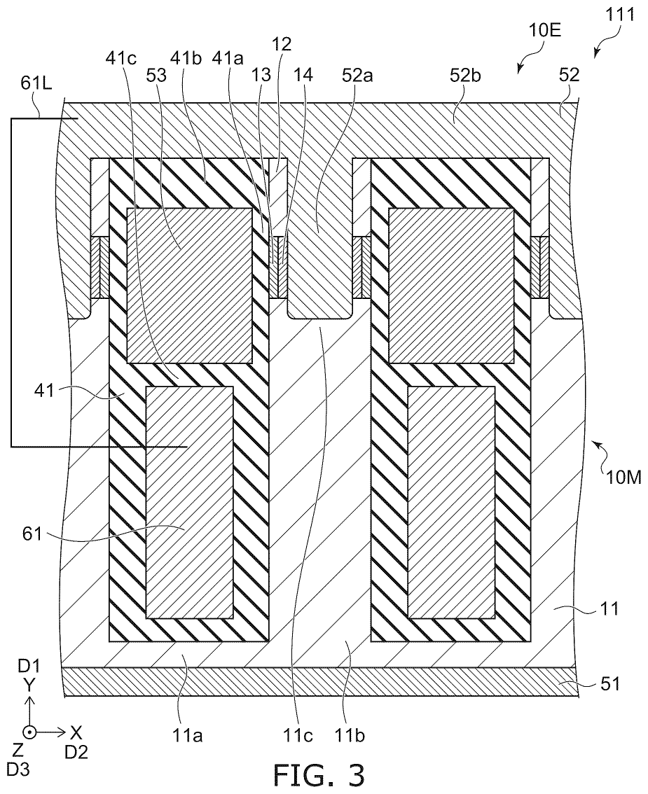

FIG. 3 is a schematic cross-sectional view illustrating a semiconductor device according to the first embodiment.

As shown in FIG. 3, in a semiconductor device 111 according to the embodiment, the configuration of the semiconductor member 10M is different from that in the semiconductor device 110. The configuration of the semiconductor device 111 except for this may be the same as the configuration of the semiconductor device 110.

In the semiconductor device 111, the semiconductor member 10M further includes a third semiconductor region 13 of the first conductivity type and a fourth semiconductor region 14 of the first conductivity type. The third semiconductor region 13 and the fourth semiconductor region 14 are between the third partial region 11c and the second semiconductor region 12 in the first direction D1. The third semiconductor region 13 is between the third electrode 53 and the first electrode portion 52a in the second direction D2. The fourth semiconductor region 14 is between the third semiconductor region 13 and the first electrode portion 52a in the second direction D2. The third semiconductor region 13 contacts the first insulating member 41. The fourth semiconductor region 14 contacts the first electrode portion 52a.

An impurity concentration of the first conductivity type (fourth impurity concentration) in the fourth semiconductor region 14 is lower than an impurity concentration of the first conductivity type (third impurity concentration) in the third semiconductor region 13. This, for example, reduces the threshold voltage. For example, the steepness of the threshold characteristic can be increased.

For example, the third impurity concentration may be between the first impurity concentration and the second impurity concentration. The fourth impurity concentration may be lower than the first impurity concentration.

The third impurity concentration may be, for example, not less than 1×10¹⁵ cm⁻³ and not more than 1×10¹⁷ cm⁻³. The fourth impurity concentration may be, for example, not less than 5×10¹⁴ cm⁻³ and not more than 8×10¹⁶ cm⁻³. The first impurity concentration may be, for example, not less than 5×10¹⁴ cm⁻³ and not more than 8×10¹⁶ cm⁻³. The second impurity concentration may be, for example, not less than 5×10¹⁴ cm⁻³ and not more than 8×10¹⁶ cm⁻³.

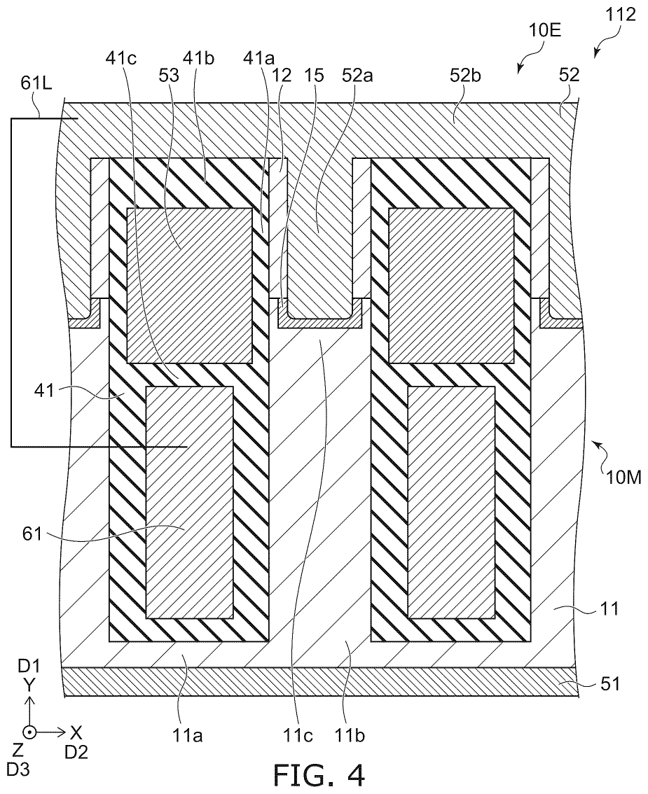

FIG. 4 is a schematic cross-sectional view illustrating a semiconductor device according to the first embodiment.

As shown in FIG. 4, in a semiconductor device 112 according to the embodiment, the configuration of the semiconductor member 10M is different from that in the semiconductor device 110. The configuration of the semiconductor device 112 except for this this may be the same as the configuration of the semiconductor device 110.

In the semiconductor device 112, the semiconductor member 10M further includes a fifth semiconductor region 15 of a second conductivity type. When the first conductivity type is n-type, the second conductivity type is p-type. When the first conductivity type is p-type, the second conductivity type is n-type.

At least a part of the fifth semiconductor region 15 is provided between the second semiconductor region 12 and the third partial region 11c in the first direction D1. In the example of FIG. 4, at least a part of the fifth semiconductor region 15 is between a part of the third electrode 53 and a part of the first electrode portion 52a in the second direction D2. By providing the fifth semiconductor region 15, for example, leakage current can be suppressed. Good characteristics can be stably obtained. In the example of FIG. 4, a part of the third partial region 11c is between the part of the third electrode 53 and at least a part of the fifth semiconductor region 15 in the second direction D2. A part of the third partial region 11c may not be in contact with the second semiconductor region 12. The fifth semiconductor region 15 may be in contact with the first insulating region 41a. A part of the first electrode portion 52a may be in contact with the third partial region 11c.

For example, another part of the fifth semiconductor region 15 may be between the third partial region 11c and the first electrode portion 52a in the first direction D1. The leakage current can be stably suppressed. A concentration of the fifth impurity of the second conductivity type in the fifth semiconductor region 15 may be, for example, not less than 1×10¹⁵ cm⁻³ and not more than 1×10¹⁸ cm⁻³. In an example in which the first electrode portion 52a contacts the fifth semiconductor region 15 of the second conductivity type (p-type), the first electrode portion 52a may include at least one element selected from the group consisting of Hf, La, Sn, Zr, Mg, V, Ti, Nb, Ta, and W, or an oxide including the above element, or a nitride including the above element. In an example in which the first electrode portion 52a contacts the fifth semiconductor region 15 of the second conductivity type (p-type), the first electrode portion 52a may include a silicide including the above element.

### Second Embodiment

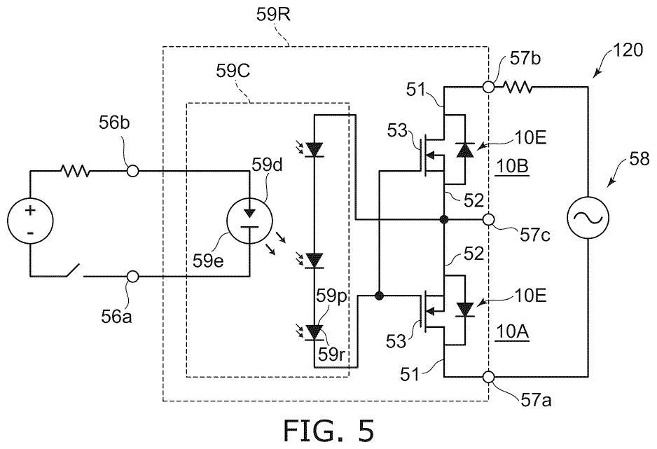

FIG. 5 is a schematic diagram illustrating a semiconductor device according to a second embodiment.

FIG. 5 is a circuit diagram of a semiconductor device 120 according to the embodiment. As shown in FIG. 5, the semiconductor device 120 includes a plurality of element portions 10E. The configuration described in relation to the first embodiment may be applied to each of the plurality of element portions 10E.

One of the plurality of element portions 10E is defined as a first element portion 10A. Another one of the plurality of element portions 10E is defined as a second element portion 10B. The second electrode 52 included in one of the plurality of element portions 10E (the first element portion 10A) is electrically connected to the second electrode 52 included in the other of the plurality of element portions 10E (the second element portion 10B). The third electrode 53 included in the one of the plurality of element portions 10E (the first element portion 10A) is electrically connected to the third electrode 53 included in the other of the plurality of element portions 10E (the second element portion 10B).

By combining two normally-ON element portions 10E, stable switch characteristics are obtained. Stable off characteristics are obtained.

A load 58 is connected between the first electrode 51 included in one of the plurality of element portions 10E (first element portion 10A) and the first electrode 51 included in the other one of the plurality of element portions 10E (second element portion 10B). The plurality of element portions 10E may be included in a photorelay 59R.

The photorelay 59R includes a photocoupler 59C and plurality of element portions 10E. The photocoupler 59C includes a light-emitting element 59e and a light-receiving element 59r. The light-emitting part of the light-emitting element 59e and the light-receiving part of the light-receiving element 59r are coupled to each other. For example, the light-emitting part of the light-emitting element 59e and the light-receiving part of the light-receiving element 59r face each other.

The emission wavelength of the light-emitting element 59e overlaps at least a part of the reception wavelength of the light-receiving element 59r. The light-emitting element 59e emits, for example, infrared light. The light-receiving element 59r receives, for example, infrared light. The light-emitting element 59e is, for example, an LED 59d.

Both ends of the light-emitting element 59e are respectively connected to two input terminals (first input terminal 56a and second input terminal 56b) of the photocoupler 59C. The light-receiving element 59r may be, for example, a photodiode 59p or a phototransistor.

In the example shown in FIG. 5, the light-receiving element 59r is a photodiode 59p. The light-receiving element 59r may include a plurality of photodiodes 59p connected in series in the same direction. Both ends of the light-receiving element 59r are connected to two output terminals of the photocoupler 59C. The anode of the light-receiving element 59r is connected to the second electrode 52 of the first element portion 10A and the second electrode 52 of the second element portion 10B. The cathode of the light-receiving element 59r is connected to the third electrode 53 of the first element portion 10A and the third electrode 53 of the second element portion 10B. The first electrode 51 of the first element portion 10A is connected to one output terminal (first output terminal 57a) of the photorelay 59R. The first electrode 51 of the second element portion 10B is connected to another output terminal (second output terminal 57b) of the photorelay 59R. The first electrode 51 of the first element portion 10A may be connected to another terminal 57c of the photorelay 59R.

The photorelay 59R includes a package that encases at least the light-emitting portion or the light-receiving portion. The package blocks light from outside. The package is omitted in FIG. 5.

When the output side power supplies is DC power, the photorelay 59R does not need to include the second element portion 10B.

When a current flows through the light-emitting element 59e on the input side, the light-emitting element 59e emits light. The light-receiving element 59r receives the light and generates an electromotive force. The gates of the first element portion 10A and the second element portion 10B are driven by the electromotive force, and these elements are turned on. The conduction state between the output terminals of the photorelay 59R can be controlled. In the first element portion 10A and the second element portion 10B, the on-resistance is low at a low gate voltage of, for example, about 0V. A normally-closed photorelay 59R that can stably pass a large current is obtained.

In the embodiment, the first insulating member 41 may include, for example, a first element and a second element. The first element includes, for example, at least one selected from the group consisting of Si, Al, and Hf. The second element includes, for example, oxygen. The second element may include nitrogen.

In the embodiment, information regarding the shape of the semiconductor region is obtained, for example, from an electron microscope image. Information regarding the composition and element concentration is obtained, for example, from EDX (Energy Dispersive X-ray Spectroscopy) or SIMS (Secondary Ion Mass Spectrometry).

The embodiment may include the following Technical proposals:

### Technical Proposal 1

A semiconductor device, comprising:
an element portion, the element portion including:
   a first electrode;
   a second electrode including a first electrode portion, a direction from the first electrode to the second electrode being along a first direction;
   a third electrode;
   a semiconductor member; and
   a first insulating member,
a second direction from the third electrode to the first electrode portion crossing the first direction,
at least a part of the first insulating member being between the third electrode and the semiconductor member,
the semiconductor member including:
   a first semiconductor region of a first conductivity type, and
   a second semiconductor region of the first conductivity type,
a second impurity concentration of the first conductivity type in the second semiconductor region being higher than a first impurity concentration of the first conductivity type in the first semiconductor region,
the first semiconductor region including a first partial region, a second partial region, and a third partial region,
the first partial region being between the first electrode and the third electrode in the first direction,
a direction from the first partial region to the second partial region being along the second direction,
the second partial region being between the first electrode and the second electrode in the first direction,
the third partial region being between the second partial region and the second electrode in the first direction,
a direction from a part of the third electrode to the third partial region being along the second direction,
at least a part of the second semiconductor region being between the third partial region and the second electrode in the first direction,
at least a part of the second semiconductor region being between the third electrode and the first electrode portion in the second direction,
the first electrode portion being in Schottky contact with the semiconductor member,
the element portion being a transistor configured to operate normally-ON.

### Technical Proposal 2

The semiconductor device according to Technical proposal 1, wherein
the first electrode portion is in contact with the first semiconductor region, and
the first electrode portion is in Schottky contact with the first semiconductor region.

### Technical Proposal 3

The semiconductor device according to Technical proposal 2, wherein
a part of the third partial region is between the third electrode and the first electrode portion in the second direction.

### Technical Proposal 4

The semiconductor device according to Technical proposal 2 or 3, wherein
the first electrode portion includes at least one selected from the group consisting of Co, Ni, and Pt.

### Technical Proposal 5

The semiconductor device according to any one of Technical proposals 1 to 4, wherein
a thickness of the second semiconductor region along the second direction is not less than 80 nm and not more than 500 nm.

### Technical Proposal 6

The semiconductor device according to any one of Technical proposals 1 to 5, wherein
the third electrode includes a first element and silicon, and
the first element includes at least one selected from the group consisting of P, As, and Sb.

### Technical Proposal 7

The semiconductor device according to any one of Technical proposals 1 to 6, wherein
the semiconductor member further includes a third semiconductor region of the first conductivity type and a fourth semiconductor region of the first conductivity type,
the third semiconductor region and the fourth semiconductor region are between the third partial region and the second semiconductor region in the first direction,
the third semiconductor region is between the third electrode and the first electrode portion in the second direction,
the fourth semiconductor region is between the third semiconductor region and the first electrode portion in the second direction, and
a fourth impurity concentration of the first conductivity type in the fourth semiconductor region is lower than a third impurity concentration of the first conductivity type in the third semiconductor region.

### Technical Proposal 8

The semiconductor device according to Technical proposal 7, wherein
the third impurity concentration is between the first impurity concentration and the second impurity concentration.

### Technical Proposal 9

The semiconductor device according to Technical proposal 7 or 8, wherein
the fourth impurity concentration is lower than the first impurity concentration.

### Technical Proposal 10

The semiconductor device according to Technical proposal 7, wherein
the third impurity concentration is not less than 1×10¹⁵ cm⁻³ and not more than 1×10¹⁷ cm⁻³, and
the fourth impurity concentration is not less than 5×10¹⁴ cm⁻³ and not more than 8×10¹⁶ cm⁻³.

### Technical Proposal 11

The semiconductor device according to any one of Technical proposals 1 to 10, wherein the first impurity concentration is not less than 5×10¹⁴ cm⁻³ and not more than 8×10¹⁶ cm⁻³, and the second impurity concentration is not less than 5×10¹⁴ cm⁻³ and not more than 8×10¹⁶ cm⁻³.

### Technical Proposal 12

The semiconductor device according to any one of Technical proposals 1 to 11, wherein
the semiconductor member further includes a fifth semiconductor region of a second conductivity type,
at least a part of the fifth semiconductor region is between the second semiconductor region and the third partial region in the first direction, and
the at least a part of the fifth semiconductor region is between the third electrode and the first electrode portion in the second direction.

### Technical Proposal 13

The semiconductor device according to Technical proposal 12, wherein
another part of the fifth semiconductor region is between the third partial region and the first electrode portion in the first direction.

### Technical Proposal 14

The semiconductor device according to Technical proposal 12 or 13, wherein
a fifth impurity concentration of the second conductivity type in the fifth semiconductor region is not less than 1×10¹⁵ cm⁻³ and not more than 1×10¹⁸ cm⁻³.

### Technical Proposal 15

The semiconductor device according to any one of Technical proposals 1 to 14, wherein
the first insulating member includes a first insulating region,
the first insulating region is between the third electrode and the second semiconductor region in the second direction, and
a thickness of the first insulating region along the second direction is not less than 20 nm and not more than 100 nm.

### Technical Proposal 16

The semiconductor device according to any one of Technical proposals 1 to 15, wherein
the element portion further includes a first conductive member,
a first conductive member position in the first direction of the first conductive member is between a first partial region position in the first direction of the first partial region and a third electrode position in the first direction of the third electrode,
the first conductive member is configured to be electrically connected to the second electrode, and
a part of the first insulating member is between the first conductive member and the third electrode and between the first conductive member and the semiconductor member.

### Technical Proposal 17

The semiconductor device according to any one of Technical proposals 1 to 16, wherein
the second electrode further includes a second electrode portion,
the third electrode is between the first partial region and the second electrode portion in the first direction, and
the second electrode portion is in ohmic contact with the second semiconductor region.

### Technical Proposal 18

The semiconductor device according to any one of Technical proposals 1 to 17, comprising two of the element portions,
the second electrode included in a first element portion being one of the two element portions being electrically connected to the second electrode included in a second element portion being other one of the two element portions, and
the third electrode included in the first element portion being electrically connected to the third electrode included in the second element portion.

### Technical Proposal 19

A photorelay circuit, comprising:
a photocoupler including a light-emitting element and a light-receiving element; and
the element portion according to Technical proposal 1,
one of two output terminals of the light-receiving element being connected to the third electrode of the element portion, and
other one of the two output terminals of the light-receiving element being connected to the second electrode of the element portion.

### Technical Proposal 20

A photorelay circuit, comprising:
a photocoupler including an LED and a photodiode;
the semiconductor device according to Technical proposal 18,
an anode of the photodiode being connected to the third electrode of the first element portion, and
a cathode of the photodiode being connected to the second electrode of the first element portion.

According to the embodiment, a semiconductor device and a photorelay circuit are provided that can improve the characteristics.

In this specification, “perpendicular” and “parallel” do not only mean strictly perpendicular and strictly parallel, but also include, for example, variations in the manufacturing process, and may mean substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and all photorelay circuits practicable by an appropriate design modification by one skilled in the art based on the semiconductor devices and the photorelay circuits described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
an element portion, the element portion including:
a first electrode;
a second electrode including a first electrode portion, a direction from the first electrode to the second electrode being along a first direction;
a third electrode;
a semiconductor member; and
a first insulating member,
a second direction from the third electrode to the first electrode portion crossing the first direction,
at least a part of the first insulating member being between the third electrode and the semiconductor member,
the semiconductor member including:
a first semiconductor region of a first conductivity type, and
a second semiconductor region of the first conductivity type,
a second impurity concentration of the first conductivity type in the second semiconductor region being higher than a first impurity concentration of the first conductivity type in the first semiconductor region,
the first semiconductor region including a first partial region, a second partial region, and a third partial region,
the first partial region being between the first electrode and the third electrode in the first direction,
a direction from the first partial region to the second partial region being along the second direction,
the second partial region being between the first electrode and the second electrode in the first direction,
the third partial region being between the second partial region and the second electrode in the first direction,
a direction from a part of the third electrode to the third partial region being along the second direction,
at least a part of the second semiconductor region being between the third partial region and the second electrode in the first direction,
at least a part of the second semiconductor region being between the third electrode and the first electrode portion in the second direction,
the first electrode portion being in Schottky contact with the semiconductor member,
the element portion being a transistor configured to operate normally-ON.

2. The semiconductor device according to claim 1, wherein
the first electrode portion is in contact with the first semiconductor region, and
the first electrode portion is in Schottky contact with the first semiconductor region.

3. The semiconductor device according to claim 2, wherein
a part of the third partial region is between the third electrode and the first electrode portion in the second direction.

4. The semiconductor device according to claim 2, wherein
the first electrode portion includes at least one selected from the group consisting of Co, Ni, and Pt.

5. The semiconductor device according to claim 1, wherein
a thickness of the second semiconductor region along the second direction is not less than 80 nm and not more than 500 nm.

6. The semiconductor device according to claim 1, wherein
the third electrode includes a first element and silicon, and
the first element includes at least one selected from the group consisting of P, As, and Sb.

7. The semiconductor device according to claim 1, wherein
the semiconductor member further includes a third semiconductor region of the first conductivity type and a fourth semiconductor region of the first conductivity type,
the third semiconductor region and the fourth semiconductor region are between the third partial region and the second semiconductor region in the first direction,
the third semiconductor region is between the third electrode and the first electrode portion in the second direction,
the fourth semiconductor region is between the third semiconductor region and the first electrode portion in the second direction, and
a fourth impurity concentration of the first conductivity type in the fourth semiconductor region is lower than a third impurity concentration of the first conductivity type in the third semiconductor region.

8. The semiconductor device according to claim 7, wherein
the third impurity concentration is between the first impurity concentration and the second impurity concentration.

9. The semiconductor device according to claim 7, wherein
the fourth impurity concentration is lower than the first impurity concentration.

10. The semiconductor device according to claim 7, wherein
the third impurity concentration is not less than 1×10¹⁵ cm⁻³ and not more than 1×10¹⁷ cm⁻³, and
the fourth impurity concentration is not less than 5×10¹⁴ cm⁻³ and not more than 8×10¹⁶ cm⁻³.

11. The semiconductor device according to claim 1, wherein the first impurity concentration is not less than 5×10¹⁴ cm⁻³ and not more than 8×10¹⁶ cm⁻³, and the second impurity concentration is not less than 5×10¹⁴ cm⁻³ and not more than 8×10¹⁶ cm⁻³.

12. The semiconductor device according to claim 1, wherein
the semiconductor member further includes a fifth semiconductor region of a second conductivity type,
at least a part of the fifth semiconductor region is between the second semiconductor region and the third partial region in the first direction, and
the at least a part of the fifth semiconductor region is between the third electrode and the first electrode portion in the second direction.

13. The semiconductor device according to claim 12, wherein
another part of the fifth semiconductor region is between the third partial region and the first electrode portion in the first direction.

14. The semiconductor device according to claim 12, wherein
a fifth impurity concentration of the second conductivity type in the fifth semiconductor region is not less than 1×10¹⁵ cm⁻³ and not more than 1×10¹⁸ cm⁻³.

15. The semiconductor device according to claim 1, wherein
the first insulating member includes a first insulating region,
the first insulating region is between the third electrode and the second semiconductor region in the second direction, and
a thickness of the first insulating region along the second direction is not less than 20 nm and not more than 100 nm.

16. The semiconductor device according to claim 1, wherein
the element portion further includes a first conductive member,
a first conductive member position in the first direction of the first conductive member is between a first partial region position in the first direction of the first partial region and a third electrode position in the first direction of the third electrode,
the first conductive member is configured to be electrically connected to the second electrode, and
a part of the first insulating member is between the first conductive member and the third electrode and between the first conductive member and the semiconductor member.

17. The semiconductor device according to claim 1, wherein
the second electrode further includes a second electrode portion,
the third electrode is between the first partial region and the second electrode portion in the first direction, and
the second electrode portion is in ohmic contact with the second semiconductor region.

18. The semiconductor device according to claim 1, comprising two of the element portions,
the second electrode included in a first element portion being one of the two element portions being electrically connected to the second electrode included in a second element portion being other one of the two element portions, and
the third electrode included in the first element portion being electrically connected to the third electrode included in the second element portion.

19. A photorelay circuit, comprising:
a photocoupler including a light-emitting element and a light-receiving element; and
the element portion according to claim 1,
one of two output terminals of the light-receiving element being connected to the third electrode of the element portion, and
other one of the two output terminals of the light-receiving element being connected to the second electrode of the element portion.

20. A photorelay circuit, comprising:
a photocoupler including an LED and a photodiode;
the semiconductor device according to claim 18,
an anode of the photodiode being connected to the third electrode of the first element portion, and
a cathode of the photodiode being connected to the second electrode of the first element portion.
